(19) United States
(12) Patent Application Publication
(10) Pub. No.: US 2026/0173734 A1
(43) Pub. Date: Jun. 18, 2026

(54) DISPLAY DEVICE

(71) Applicant: LG Display Co., Ltd., Seoul (KR)

(72) Inventor: Jaeyoung KWAK, Paju-si (KR)

(73) Assignee: LG Display Co., Ltd., Seoul (KR)

(21) Appl. No.: 19/361,611

(22) Filed: Oct. 17, 2025

(30) Foreign Application Priority Data
Dec. 18, 2024 (KR) 10-2024-0189738

(51) Int. Cl. H10K 59/80; H10K 59/35; H10K 102/10

(52) U.S. Cl. CPC H10K 59/876; H10K 59/35; H10K 59/80517; H10K 59/80518; H10K 2102/102; H10K 2102/103

(57) ABSTRACT

A display device is provided, wherein a first light emitting device generates a first microcavity and a second microcavity between a first electrode and a second electrode, and a second light emitting device generates a third microcavity between the first electrode and the second electrode. The display device includes a substrate having a plurality of sub pixels, each sub pixel comprising a light emitting device with a first electrode on the substrate, a light emitting layer on the first electrode, and a second electrode on the light emitting layer. The first light emitting device forms the first and second micro cavities for light of different wavelength bands, and the second light emitting device forms the third microcavity for light of another wavelength band, thereby enabling control of optical properties including spectrum width, luminance, and color balance in the display device.

### CROSS-REFERENCE TO RELATED APPLICATIONS

This application claims the benefit of the Republic of Korea Patent Application No. 10-2024-0189738 filed on December 18, 2024, each of which is hereby incorporated by reference in its entirety.

### BACKGROUND

### TECHNICAL FIELD

The present disclosure relates to a display device.

### DESCRIPTION OF THE RELATED ART

As an information society develops, a demand for a display device for displaying an image is increasing in various forms. Accordingly, various display devices such as a liquid crystal display (LCD), a plasma display panel (PDP), and an organic light emitting display (OLED) have recently been used.

Among the display devices, the organic light emitting display device is a self-luminous type, has better viewing angle and contrast ratio than the liquid crystal display (LCD), and has an advantage of being lightweight and thin because a separate backlight is not required, and power consumption is advantageous. In addition, the organic light emitting display device has an advantage of being driven with a low DC voltage, having a fast response speed, and especially low manufacturing cost.

### BRIEF SUMMARY

The present disclosure has been developed in view of the technical problems in the related art, and one aspect of the present disclosure is to provide an organic light emitting device having improved optical characteristics, including luminance with respect to viewing angle, color stability across different viewing angles, and enhanced front emission efficiency, as well as a display device incorporating such a device.

The aspects described focus on a multi microcavity architecture in the OLED display device. By incorporating both reflective and transflective electrodes in the first light emitting device, the design creates multiple optical cavities with different optical distances, broadening the emission spectrum while maintaining light intensity. This enables improved luminance uniformity across viewing angles and precise control of color balance by shifting specific cavities toward shorter wavelength regions.

Another important aspect is the layered electrode structure using reflective metals such as aluminum or silver, transparent conductive materials such as ITO or IZO, and transflective layers whose thickness can be adjusted to control transmittance, reflectance, and the full width at half maximum of emitted light. By selectively configuring sub pixels with green using multiple cavities for viewing angle stability, blue using a single cavity for on axis efficiency, and red with adjustable thickness for color balance, the design achieves pixel level optical customization while sharing common layers such as reflective electrodes and capping layers to reduce manufacturing complexity.

Finally, the use of a transflective second electrode allows light emission while contributing to microcavity resonance, improving efficiency without reducing brightness. Overall, one or more of multi cavity resonance, adjustable optical layer thickness, and pixel specific electrode configurations, alone or in combination, may provide enhanced brightness, color accuracy, and viewing angle performance for OLED displays.

For example, in accordance with an aspect of the present disclosure, the above and other technical effects can be accomplished by the provision of a display device comprising a plurality of sub-pixels including an emission area and a non-emission area surrounding the emission area, and each of the plurality of sub-pixels include a first electrode disposed on the substrate in the emission area, a first stack disposed on the first electrode, a doping prevention layer disposed on the first stack, and an n-type charge generation layer disposed on the doping prevention layer, wherein the n-type charge generation layer includes a doped region including an n-type dopant material and an undoped region not including the n-type dopant material, and wherein the doping prevention layer does not overlap the doped region and overlaps the undoped region.

It is to be understood that both the foregoing general description and the following detailed description are exemplary and explanatory and are intended to provide further explanation of the inventive concepts as claimed

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description explain the principle of the disclosure. In the drawings:

FIG. 1 is a plan view of a display device according to an embodiment of the present disclosure;

FIG. 2 is a plan view of one pixel according to an embodiment of the present disclosure;

FIG. 3 is a cross-sectional view of one sub-pixel according to an embodiment of the present disclosure;

FIG. 4 is a cross-sectional view of a light emitting device according to a first embodiment of the present disclosure;

FIG. 5 is a graph illustrating an intensity of light of a light emitting device of FIG. 4;

FIG. 6 is a cross-sectional view of a conventional light emitting device;

FIG. 7 is a cross-sectional view of a light emitting device according to a second embodiment of the present disclosure;

FIG. 8 is a cross-sectional view of a light emitting device according to a third embodiment of the present disclosure;

FIG. 9 is a graph illustrating transmittance of a transflective electrode of the light emitting device of FIG. 7;

FIG. 10 is a graph illustrating an intensity of light of a light emitting device of FIG. 7; and

FIG. 11 is a cross-sectional view of a light emitting device according to a fourth embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art.

A shape, a size, a ratio, an angle, and a number disclosed in the accompanying drawings for describing the examples of the present disclosure are merely illustrative and, thus, the present disclosure is not limited to the illustrated details. Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where ‘comprise’, ‘have’, and ‘include’ described in the present disclosure are used, another portion may be added unless ‘only~’ is used. The terms of a singular form may include plural forms unless referred to the contrary.

In interpreting the components, it is interpreted as including an error range even if there is no separate explicit description of an error range.

In describing a position relationship, for example, when the position relationship is described as ‘upon~’, ‘above~’, ‘below~’ and ‘next to~’, one or more portions may be disposed between two other portions unless ‘just’ or ‘direct’ is used. The terms, such as “below,” “lower,” “above,” “upper”, and the like, may be used herein to describe a relationship between elements as illustrated in the drawings. It will be understood that the terms are spatially relative and based on the orientation depicted in the drawings.

As used herein, the phrase “at least one of A and B” (and similar phrases using “at least one of”) is intended to mean A alone, B alone, or both A and B together. When applied to longer lists, such as “at least one of A, B, and C”, the phrase is intended to mean any one of A, B, or C individually, or any combination of A, B, and C, including all three together, unless otherwise expressly stated. The phrase should be interpreted in the broadest reasonable manner and is not intended to require every element in the list to be present unless explicitly specified.

A description of a time relationship may include a case in which the temporal precedence relationship is described as “after”, “following”, or “before”, etc., and is not continuous unless “right away” or “directly”, is used.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)”, etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of each of the various examples of the present disclosure may be partially or entirely coupled or combined with each other, technically various interworking and driving are possible, and each of the examples may be independently implemented with respect to each other or may be implemented together in a related relationship.

Hereinafter, one embodiment of the present disclosure will be described in detail with reference to the accompanying drawings.

FIG. 1 is a plan view of a display device according to an embodiment of the present disclosure.

Referring to FIG. 1, the display device 10 according to an embodiment of the present disclosure may include a display area DA and a non-display area NDA surrounding the display area DA. The display area DA is an area in which an image may be displayed, and the non-display area NDA is an area in which an image is not displayed.

The display area DA may include a plurality of pixels P. The plurality of pixels P may be arranged in a matrix form consisting of a plurality of rows and columns. In addition, the non-display area NDA may include a plurality of wirings, pads, driving circuits, etc., for driving the plurality of pixels P.

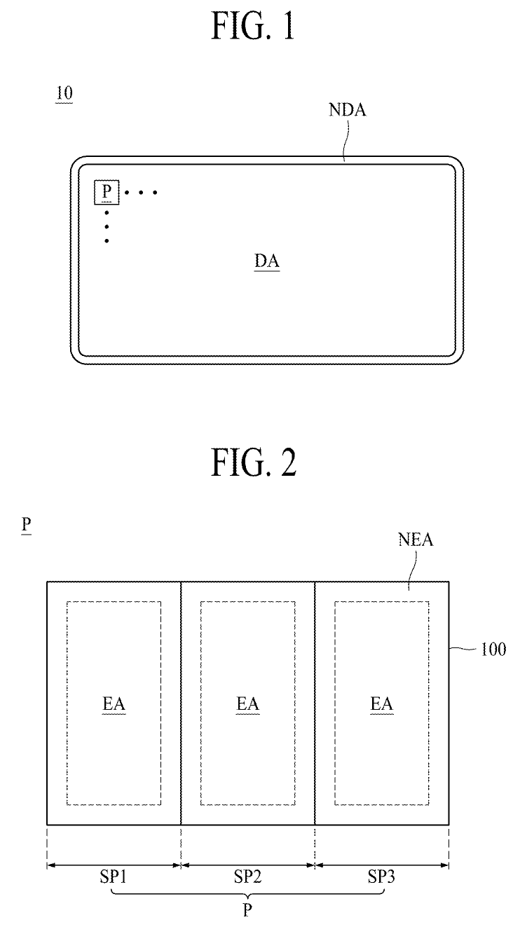

FIG. 2 is a plan view of one pixel according to an embodiment of the present disclosure.

Referring to FIG. 2, one pixel P may include a first sub-pixel SP1, a second sub-pixel SP2, and a third sub-pixel SP3. The first sub-pixel SP1, the second sub-pixel SP2, and the third sub-pixel SP3 may emit different light from each other. For example, the first sub-pixel SP1 may emit red light, the second sub-pixel SP2 may emit green light, and the third sub-pixel SP3 may emit blue light, but the present disclosure is not limited thereto. In addition, FIG. 2 shows that one pixel P includes three sub-pixels SP1 to SP3, but is not limited thereto. For example, one pixel P may include more than three sub-pixels.

The first sub-pixel SP1, the second sub-pixel SP2, and the third sub-pixel SP3 may be disposed on a substrate 100. Each of the first sub-pixel SP1, the second sub-pixel SP2, and the third sub-pixel SP3 may include an emission area EA and a non-emission area NEA surrounding the emission area EA. The emission area EA is an area capable of emitting light, and the non-emission area NEA is an area that does not emit light

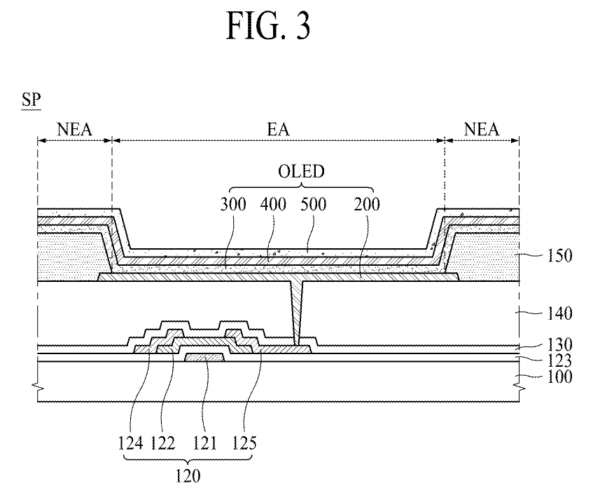

FIG. 3 is a cross-sectional view of one sub-pixel SP according to a first embodiment of the present disclosure. FIG. 3 is a cross-sectional view of any one of the first sub-pixel SP1, the second sub-pixel SP2, and the third sub-pixel SP3 shown in FIG. 2.

Referring to FIG. 3, one sub-pixel SP according to an embodiment of the present disclosure may include a substrate 100, a thin film transistor 120, a passivation layer 130, a planarization layer 140, a bank 150, and a light emitting device OLED.

The substrate 100 may be made of glass or plastic, but is not limited thereto. The display device according to an embodiment of the present disclosure may be configured in a top emission type in which light is emitted upward. Therefore, as a material of the substrate 100, not only a transparent material but also an opaque material may be used.

The thin film transistor 120 may be disposed on the substrate 100. The thin film transistor 120 may include a gate electrode 121, a semiconductor layer 122, a gate insulating layer 123, a source electrode 124, and a drain electrode 125.

The gate electrode 121 of the thin film transistor 120 may be disposed on the substrate 100. In addition, the semiconductor layer 122 may be disposed on the gate electrode 121. The semiconductor layer 122 may include a poly-silicon semiconductor or an oxide semiconductor. In addition, when the semiconductor layer 122 includes the oxide semiconductor, at least one oxide of indium-gallium-zinc-oxide (IGZO), indium-gallium-tin-oxide (IGO), and indium-gallium-oxide (IGO) may be included.

The gate insulating layer 123 for insulating the gate electrode 121 and the semiconductor layer 122 may be disposed between the gate electrode 121 and the semiconductor layer 122. The gate insulating layer 123 may be formed of a single layer of silicon nitride (SiNx) or silicon oxide (SiOx), or multiple layers thereof. In addition, FIG. 3 illustrates a bottom gate structure in which the semiconductor layer 122 is disposed on the gate electrode 121, but is not limited thereto. For example, a top gate structure in which the gate electrode 121 is disposed on the semiconductor layer 122 may be disclosed.

The source electrode 124 and the drain electrode 125 may be disposed on the semiconductor layer 122 while facing each other. In addition, the passivation layer 130 may be disposed on the source electrode 124 and the drain electrode 125. A contact hole exposing a portion of the drain electrode 124 may be disposed in the passivation layer 130. In addition, the passivation layer 130 may be formed of an inorganic insulating material such as silicon oxide (SiOx), silicon nitride (SiNx), silicon oxynitride (SiOxNy), or the like.

The planarization layer 140 may be disposed on the thin film transistor 120. The planarization layer 140 may compensate for a step difference caused by the thin film transistor 120 to form a flat upper area of the thin film transistor 120. In addition, the planarization layer 140 may be formed of an organic insulating material such as an acrylic resin, an epoxy resin, a phenolic resin, a polyamide resin, or a polyimide resin.

The bank 150 may be disposed on the planarization layer 140 and in the non-emission area NEA. The bank 150 may expose a partial area of the planarization layer 140.

The light emitting device OLED may be disposed on the planarization layer 140. The light emitting device OLED may include a first electrode 200, a light emitting layer 300, a second electrode 400, and a capping layer 500.

The first electrode 200 is disposed on the planarization layer 140 and may function as an anode of the display device. The first electrode 200 may be electrically connected to the drain electrode 125 of the thin film transistor 120 through a contact hole disposed in the passivation layer 130 and the planarization layer 140.

The first electrode 200 may be disposed on the planarization layer 140 exposed by the bank 150. An end of the first electrode 200 may be covered by the bank 150. The first electrode 200 may be disposed in the emission area EA

The light emitting layer 300 may be disposed on the first electrode 200. The light emitting layer 300 may cover an entire upper surface of the first electrode 200 that is not covered by the bank 150. In addition, the light emitting layer 300 may be disposed on the bank 150. That is, the light emitting layer 300 may be disposed in the emission area EA and the non-emission area NEA.

The second electrode 400 may be disposed on the light emitting layer 300. The second electrode 400 may function as a cathode of the display device. Like the light emitting layer 300, the second electrode 400 may also be disposed on the bank 150. That is, the second electrode 400 may be disposed in the emission area EA and the non-emission area NEA.

The capping layer 500 may be disposed on the second electrode 400. The capping layer 500 may cover an entire surface of the second electrode 400 and protect the light emitting device OLED. That is, the capping layer 500 may be disposed in the emission area EA and the non-emission area NEA.

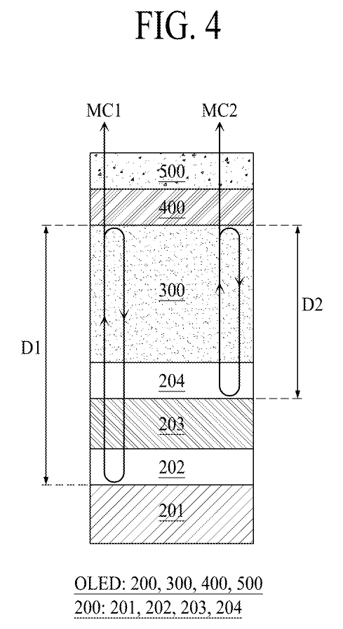

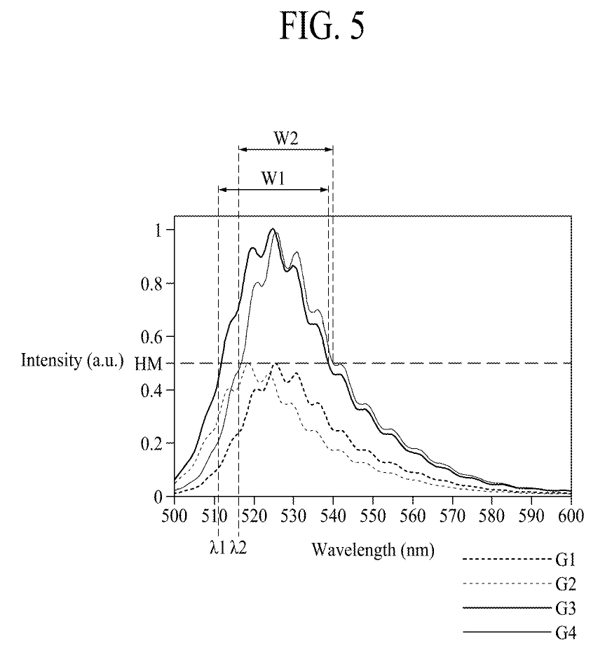

FIG. 4 is a cross-sectional view of a light emitting device according to a first embodiment of the present disclosure. FIG. 4 illustrates the light emitting device OLED of any one of the first to third subpixels SP1 to SP3.

As described above, the light emitting device OLED may include a first electrode 200, a light emitting layer 300, a second electrode 400, and a capping layer 500.

The first electrode 200 functions as an anode and may provide holes to the light emitting layer 300. The first electrode 200 may include a reflective electrode 201, a first transparent electrode 202, a transflective electrode 203, and a second transparent electrode 204.

The reflective electrode 201 may include a metal material such as aluminum (Al), silver (Ag), copper (Cu), molybdenum (Mo), titanium (Ti), tungsten (W), or chromium (Cr), or an alloy thereof. In this case, the reflective electrode 201 may have a sufficient thickness to reflect incident light.

The first transparent electrode 202 may be disposed on the reflective electrode 201. The first transparent electrode 202 may include a transparent conductive material such as indium tin oxide (ITO) or indium zinc oxide (IZO).

The transflective electrode 203 may be disposed on the first transparent electrode 202. The transflective electrode 203 may include a metal material such as aluminum (Al), silver (Ag), copper (Cu), molybdenum (Mo), titanium (Ti), tungsten (W), or chromium (Cr), or an alloy thereof. The transflective electrode 203 may include the same material as the reflective electrode 201, but is not limited thereto. In this case, the transflective electrode 203 may have a thickness such that a part of incident light may be transmitted and a part of incident light may be reflected. That is, a thickness of the transflective electrode 203 may be less than a thickness of the reflective electrode 201.

The second transparent electrode 204 may be disposed on the transflective electrode 203. The second transparent electrode 204 may include a transparent conductive material such as indium tin oxide (ITO) or indium zinc oxide (IZO). The second transparent electrode 204 may include the same material as the first transparent electrode 202, but is not limited thereto.

The light emitting layer 300 may be disposed on the first electrode 200. The light emitting layer 300 may include a hole transport layer, an emission layer, and an electron transport layer. In this case, when a voltage is applied to the first electrode 200 and the second electrode 400, holes and electrons move to the emission layer through the hole transport layer and the electron transport layer, respectively, and may combine in the emission layer with each other to emit light.

The second electrode 400 may be disposed on the light emitting layer 300. The second electrode 400 may provide electrons to the light emitting layer 300.

The second electrode 400 may be a transflective electrode. The second electrode 400 may include a metal material such as aluminum (Al), silver (Ag), copper (Cu), molybdenum (Mo), titanium (Ti), tungsten (W), or chromium (Cr), or an alloy thereof. The second electrode 400 may include the same material as the transflective electrode 203, but is not limited thereto. In this case, the second electrode 400 may have a thickness such that a part of incident light may be transmitted and a part of incident light may be reflected. Accordingly, the second electrode 400 may emit light generated in the light emitting layer 300 to the outside.

The capping layer 500 may be disposed on the second electrode 400. The capping layer 500 may be formed of an inorganic insulating material such as silicon oxide (SiOx), silicon nitride (SiNx), silicon oxynitride (SiOxNy), or the like. In addition, the capping layer 500 may transmit light generated by the light emitting layer 300.

Meanwhile, microcavity characteristics may be generated by the first electrode 200 and the second electrode 400. In detail, when a distance between the first electrode 200 and the second electrode 400 becomes an integer multiple of a half wavelength of light generated in the light emitting layer 300, constructive interference may occur and light may be amplified. That is, a reflection and a re-reflection of the light are repeated between the first electrode 200 and the second electrode 400, and a degree to which the light is amplified may be continuously increased. Accordingly, efficiency to which light generated in the light emitting layer 300 is emitted to the outside may be improved.

Referring to FIG. 4, since the reflective electrode 201 may reflect light, the microcavity characteristic may be generated between the reflective electrode 201 and the second electrode 400. In this case, a distance between the reflective electrode 201 and the second electrode 400 is a first optical distance D1, and the microcavity characteristic generated by the reflective electrode 201 and the second electrode 400 may be referred to as a first microcavity MC1.

In addition, since the transflective electrode 203 may reflect a part of incident light, the microcavity characteristic may be generated between the transflective electrode 203 and the second electrode 400. In this case, a distance between the transflective electrode 203 and the second electrode 400 is a second optical distance D2, and the microcavity characteristic generated by the transflective electrode 203 and the second electrode 400 may be referred to as a second microcavity MC2. In addition, the second optical distance D2 may be less than the first optical distance D1.

That is, since the first microcavity MC1 and the second microcavity MC2 are generated at different optical distances, a wavelength band of light to be amplified by the first microcavity MC1 and the second microcavity MC2 may be different. Accordingly, according to the present disclosure, by disclosing the first electrode 200 including the reflective electrode 201 and the transflective electrode 203, microcavity characteristics according to different optical distances may be simultaneously generated.

FIG. 5 is a graph illustrating an intensity of light of a light emitting device of FIG. 4. Specifically, FIG. 5 shows a relative intensity of light according to wavelengths. That is, the intensity of light shown in FIG. 5 is not an absolute value, but a value for relative comparison. In addition, FIG. 5 shows a case where the light emitting layer 300 of the light emitting device OLED is a green light emitting layer, but is not limited thereto. The light emitting layer 300 of the light emitting device OLED may be a red or blue light emitting layer.

That is, a partial area of the first graph G1 and the second graph G2 may overlap, and a partial area of the first graph G1 and the second graph G2 may not overlap. In addition, a maximum value of the first graph G1 and a maximum value of the second graph G2 may be different from each other. In addition, the second graph G2 may be shifted to a shorter wavelength area than the first graph G1.

The third graph G3 is an intensity of light finally emitted from the light emitting device OLED shown in FIG. 4. The light finally emitted from the light emitting device OLED may be light obtained by adding reinforcement interference by the first microcavity MC1 and reinforcement interference by the second microcavity MC2 to light generated by the light emitting layer 300. That is, the light generated by the light emitting layer of the light emitting device OLED includes a wavelength band of the light amplified by the first microcavity MC1 and the second microcavity MC2, and the intensity of the light finally emitted from the light emitting device OLED may be amplified by the first microcavity MC1 and the second microcavity MC2.

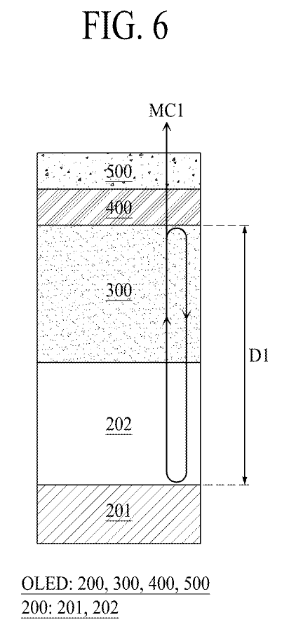

The fourth graph G4 is an intensity of light finally emitted from a conventional light emitting device OLED. Referring to FIG. 6, a first electrode 200 of the conventional light emitting device OLED may include a reflective electrode 201 and a first transparent electrode 202 disposed on the reflective electrode 201. That is, unlike the light emitting device OLED disclosed in FIG. 4, the conventional light emitting device OLED does not include the transflective electrode 203 and the second transparent electrode 204. Accordingly, the conventional light emitting device OLED may generate only the first microcavity MC1. That is, the light finally emitted from the conventional light emitting device OLED may be light obtained by adding reinforcement interference by the first microcavity MC1 to the light generated by the light emitting layer 300.

Referring to FIG. 5, a maximum value of the third graph G3 may be similar to a maximum value of the fourth graph G4. In contrast, a full width at half maximum (FWHM) W1 of the third graph G3 may be greater than a full width at half maximum (FWHM) W2 of the fourth graph G4. Specifically, a full width at half maximum (FWHM) may be a full width of the graph at half the maximum value (HM) of the graph. The third graph G3 may have a half value HM of a maximum value at a first wavelength λ1, and the fourth graph G4 may have a half value HM of a maximum value at a second wavelength λ2. In this case, the first wavelength λ1 may be shorter than the second wavelength λ2. That is, compared with the fourth graph G4, the third graph G3 may have a similar light intensity and a wider light spectrum.

Accordingly, the present disclosure discloses the first microcavity MC1 and the second microcavity MC2 according to different optical distances, thereby widening a width of a spectrum of light while maintaining a intensity of light. Accordingly, it is possible to improve luminance reduction according to a viewing angle.

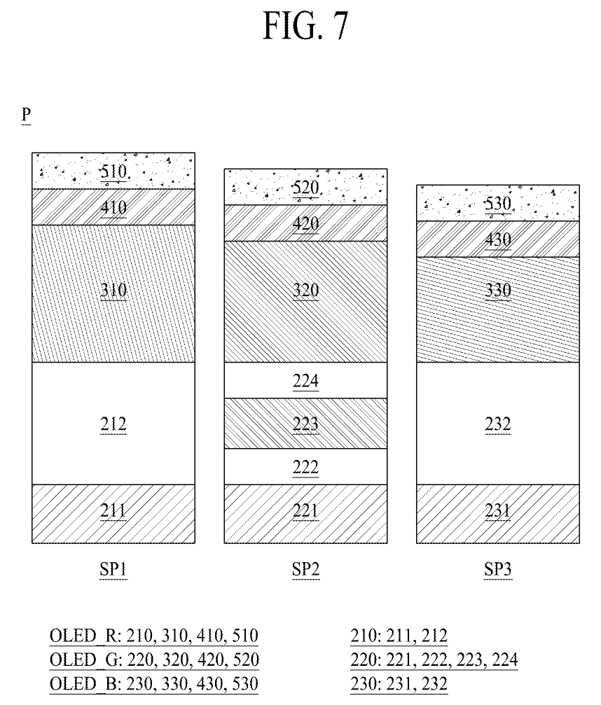

FIG. 7 is a cross-sectional view of a light emitting device according to a second embodiment of the present disclosure. Specifically, FIG. 7 illustrates a cross-sectional view of a light emitting device of each of the first sub-pixel SP1, the second sub-pixel SP2, and the third sub-pixel SP3.

The first sub-pixel SP1 may include a red light emitting device OLED_R. The red light emitting device OLED_R may include a first electrode 210, a light emitting layer 310, a second electrode 410, and a capping layer 510. The first electrode 210 of the red light emitting device OLED_R may include a reflective electrode 211 and a first transparent electrode 212. That is, the first electrode 210 of the red light emitting device OLED_R may have a structure of the first electrode 200 shown in FIG. 6. Accordingly, only the first microcavity MC1 may be generated. In addition, the light emitting layer 310 may generate the red light.

The second sub-pixel SP2 may include the green light emitting device OLED_G. The green light emitting device OLED_G may include a first electrode 220, a light emitting layer 320, a second electrode 420, and a capping layer 520. The first electrode 220 of the green light emitting device OLED_G may include a reflective electrode 221, a first transparent electrode 222, a transflective electrode 223, and a second transparent electrode 224. That is, the first electrode 220 of the green light emitting device OLED_G may have a structure of the first electrode 200 shown in FIG. 4. Accordingly, the first microcavity MC1 and the second microcavity MC2 may be generated. In addition, the light emitting layer 320 may generate green light.

The third sub-pixel SP3 may include the blue light emitting device OLED_B. The blue light emitting device OLED_B may include a first electrode 230, a light emitting layer 330, a second electrode 430, and a capping layer 530. The first electrode 230 of the blue light emitting device OLED_B may include a reflective electrode 231 and a first transparent electrode 232. That is, the first electrode 230 of the blue light emitting device OLED_B may have a structure of the first electrode 200 shown in FIG. 6. Accordingly, only the first microcavity MC1 may be generated. In addition, the light emitting layer 330 may generate the blue light.

The first electrodes 210, 220, and 230 of the red light emitting device OLED_R, the green light emitting device OLED_G, and the blue light emitting device OLED_B may be disposed in each of the first sub-pixel SP1, the second sub-pixel SP2, and the third sub-pixel SP3.

The reflective electrodes 211, 221, and 231 of the red light emitting device OLED_R, the green light emitting device OLED_G, and the blue light emitting device OLED_B may be formed in common. In addition, the second electrodes 410, 420, and 430 of the red light emitting device OLED_R, the green light emitting device OLED_G, and the blue light emitting device OLED_B may be formed in common. In addition, the capping layers 510, 520, and 530 of the red light emitting device OLED_R, the green light emitting device OLED_G, and the blue light emitting device OLED_B may be formed in common.

The first electrodes 210 and 230 of the red light emitting device OLED_R and the blue light emitting device OLED_B may have the same structure. In addition, the first electrode 220 of the green light emitting device OLED_G may have a different structure from the first electrodes 210 and 230 of the red light emitting device OLED_R and the blue light emitting device OLED_B. That is, a structure of the first electrode may be selectively set for each light emitting device OLED of each sub-pixel SP.

FIG. 7 discloses that the first electrode 220 of the second light emitting device OLED2 includes the reflective electrode 221, the first transparent electrode 222, the transflective electrode 223, and the second transparent electrode 224, but is not limited thereto. For example, a same structure as the first electrode 220 of the second light emitting device OLED2 may be applied to the first light emitting device OLED1 or the third light emitting device OLED3.

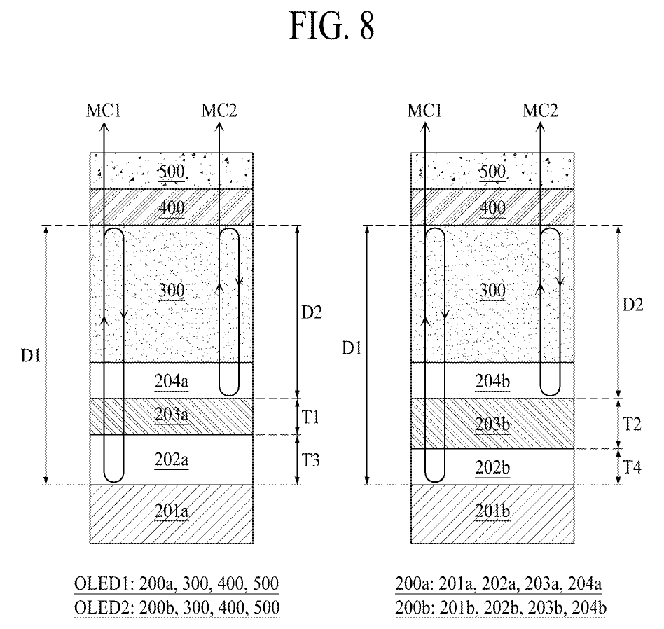

FIG. 8 is a cross-sectional view of a light emitting device according to a third embodiment of the present disclosure. Specifically, in the light emitting device OLED disclosed in FIG. 4, it is illustrated that a thickness of the transflective electrode 203 of the first electrode 200 is adjusted.

Referring to FIG. 8, a first light emitting device OLED1 may include a first electrode 200a, a light emitting layer 300, a second electrode 400, and a capping layer 500. The first electrode 200a of the first light emitting device OLED1 may include a reflective electrode 201a, a first transparent electrode 202a, a transflective electrode 203a, and a second transparent electrode 204a.

Likewise, a second light emitting device OLED2 may include a first electrode 200b, a light emitting layer 300, a second electrode 400, and a capping layer 500. The first electrode 200b of the second light emitting device OLED2 may include a reflective electrode 201b, a first transparent electrode 202b, a transflective electrode 203b, and a second transparent electrode 204b.

That is, the first light emitting device OLED1 and the second light emitting device OLED2 may have the same stack structure.

The transflective electrode 203a of the first light emitting device OLED1 may have a first thickness T1, and the transflective electrode 203b of the second light emitting device OLED2 may have a second thickness T2. The first thickness T1 may be less than the second thickness T2. In addition, the first transparent electrode 202a of the first light emitting device OLED1 may have a third thickness T3, and the first transparent electrode 202b of the second light emitting device OLED2 may have a fourth thickness T4. The third thickness T3 may be greater than the fourth thickness T4. In addition, a sum of the first thickness T1 and the third thickness T3 may be the same as a sum of the second thickness T2 and the fourth thickness T4

Accordingly, thicknesses of the transflective electrodes 203a and 203b may be adjusted while the second optical distances D2 of the first light emitting device OLED1 and the second light emitting device OLED2 are maintained the same. Therefore, the first light emitting device OLED1 and the second light emitting device OLED2 may generate the second microcavity MC2 the same.

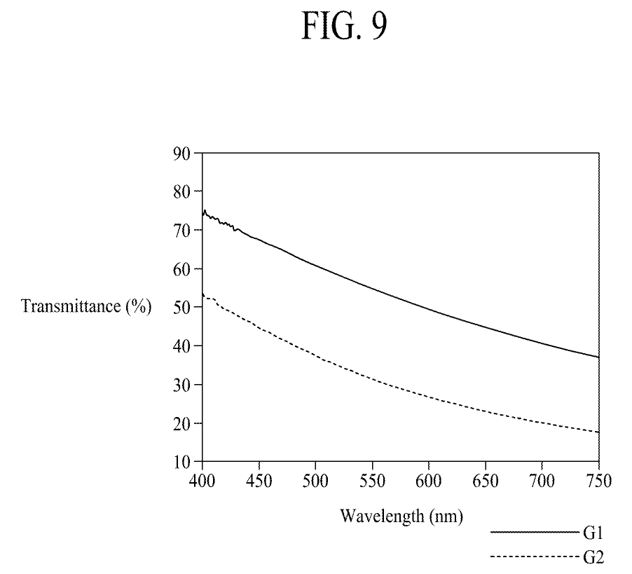

FIG. 9 is a graph illustrating transmittance of a transflective electrode of the light emitting device of FIG. 7.

Referring to FIG. 9, a first graph G1 shows a transmittance of the transflective electrode 203a of the first light emitting device OLED1, and a second graph G2 shows a transmittance of the transflective electrode 203b of the second light emitting device OLED2. As described above, the first thickness T1 of the transflective electrode 203a of the first light emitting device OLED1 may be smaller than the second thickness T2 of the transflective electrode 203b of the second light emitting device OLED2. Accordingly, in all wavelength bands, the transmittance of the transflective electrode 203a of the first light emitting device OLED1 may be higher than the transmittance of the transflective electrode 203b of the second light emitting device OLED2. On the contrary, in all wavelength bands, a reflectance of the transflective electrode 203a of the first light emitting device OLED1 may be lower a reflectance that of the transflective electrode 203b of the second light emitting device OLED2. That is, by adjusting the thicknesses of the transflective electrodes 203a and 203b, the transmittance and the reflectance of the transflective electrodes 203a and 203b may be set.

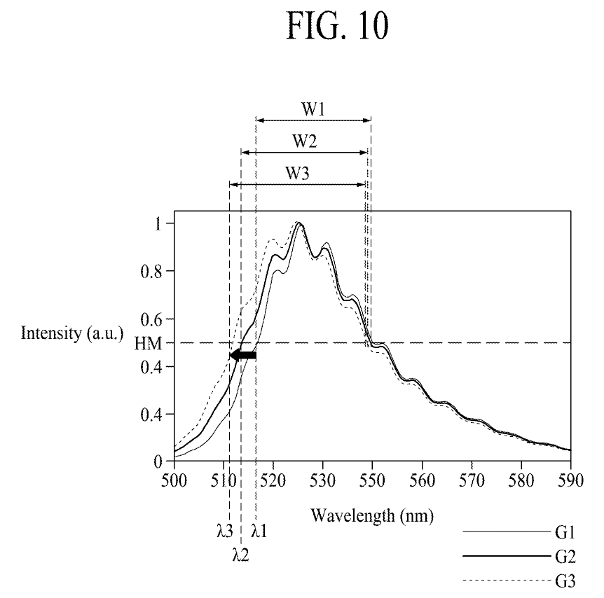

FIG. 10 is a graph illustrating an intensity of light of a light emitting device of FIG. 7. Specifically, FIG. 10 shows a relative intensity of light according to wavelengths. That is, the intensity of light shown in FIG. 10 is not an absolute value, but a value for relative comparison. In addition, FIG. 10 shows a case where the light emitting layer 300 of the light emitting device OLED is a green light emitting layer, but is not limited thereto. The light emitting layer 300 of the light emitting device OLED may be a red or blue light emitting layer

A first graph G1 is an intensity of light finally emitted from a conventional light emitting device OLED. As described above in FIGS. 5 and 6, the light finally emitted from the conventional light emitting device OLED may be light obtained by adding reinforcement interference by the first microcavity MC1 to the light generated by the light emitting layer 300.

A second graph G2 is an intensity of light finally emitted from the first light emitting device OLED1 shown in FIG. 8. A third graph 32 is an intensity of light finally emitted from the second light emitting device OLED2 shown in FIG. 8. The light finally emitted from each of the first light emitting device OLED1 and the second light emitting device OLED2 may be light obtained by adding reinforcement interference by the first microcavity MC1 and reinforcement interference by the second microcavity MC2 to light generated by the light emitting layer 300.

Referring to FIG. 10, maximum values of the first graph G1, the second graph G2, and the third graph G3 may be similar to each other. On the other hand, a full width at half maximum (FWHM) W2 of the second graph G2 may be greater than a full width at half maximum (FWHM) W1 of the first graph G1, and a full width at half maximum (FWHM) W3 of the third graph G3 may be greater than the full width at half maximum (FWHM) W2 of the second graph G2. Specifically, a full width at half maximum (FWHM) may be a full width of the graph at half the maximum value (HM) of the graph. A first wavelength λ1 may be a short wavelength value of the FWHM W1 in the first graph G1, a second wavelength λ2 may be a short wavelength value of the FWHM W2 in the second graph G2, and a third wavelength λ3 may be a short wavelength value of the FWHM W3 in the third graph G3. In this case, the first wavelength λ1 may be longer than the second wavelength λ2, and the second wavelength λ2 may be longer than the third wavelength λ3.

That is, compared with the first graph G1, each of the second graph G2 and the third graph G3 may have similar intensity of light and may have a wider width of the light spectrum. Also, compared with the second graph G2, the third graph G3 may have similar intensity of light and may have a wider width of the light spectrum.

As described in FIG. 8, a second thickness T2 of the transflective electrode 203b of the second light emitting device OLED2 may be greater than a first thickness T1 of the transflective electrode 203a of the first light emitting device OLED1. In addition, as described in FIG. 9, as a thickness of the transflective electrode increases, a transmittance decreases, and thus a reflectance may increase. Accordingly, the reinforcing interference by the second microcavity MC2 generated in the second light emitting device OLED2 may increase compared to that of the first light emitting device OLED1. Accordingly, by adjusting the thickness of the transflective electrode, the width of the spectrum of light may be adjusted. In particular, the FWHM of the spectrum of light may be adjusted.

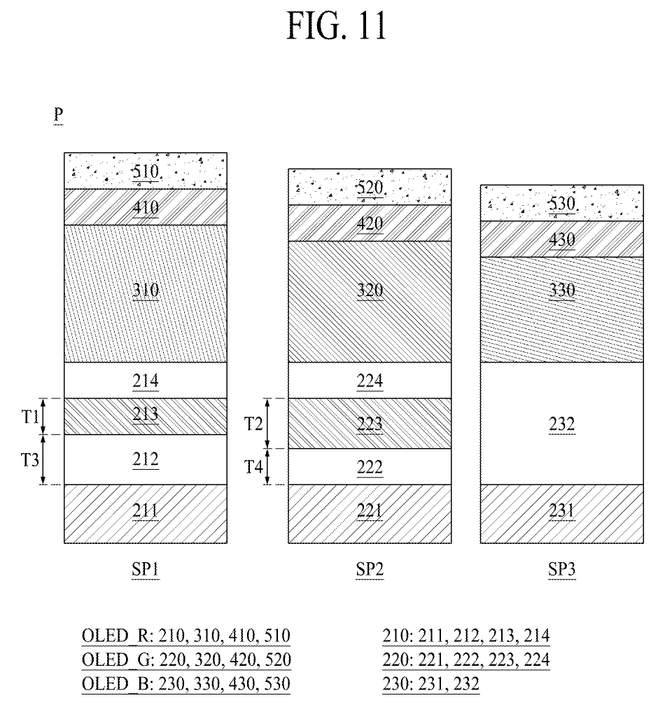

FIG. 11 is a cross-sectional view of a light emitting device according to a fourth embodiment of the present disclosure. Specifically, FIG. 11 illustrates a cross-sectional view of a light emitting device of each of the first sub-pixel SP1, the second sub-pixel SP2, and the third sub-pixel SP3.

The first sub-pixel SP2 may include the red light emitting device OLED_R. The red light emitting device OLED_G may include a first electrode 210, a light emitting layer 310, a second electrode 410, and a capping layer 510. The first electrode 210 of the red light emitting device OLED_R may include a reflective electrode 211, a first transparent electrode 212, a transflective electrode 213, and a second transparent electrode 214. In addition, the transflective electrode 213 of the red light emitting device OLED_R may have a first thickness T1. That is, the first electrode 210 of the red light emitting device OLED_R may have a structure of the first electrode 200a of the first light emitting device shown in FIG. 8. Accordingly, the first microcavity MC1 and the second microcavity MC2 may be generated. In addition, the light emitting layer 310 may generate red light.

The second sub-pixel SP2 may include the green light emitting device OLED_G. The green light emitting device OLED_G may include a first electrode 220, a light emitting layer 320, a second electrode 420, and a capping layer 520. The first electrode 220 of the green light emitting device OLED_G may include a reflective electrode 221, a first transparent electrode 222, a transflective electrode 223, and a second transparent electrode 224. In addition, the transflective electrode 223 of the green light emitting device OLED_G may have a second thickness T2. That is, the first electrode 220 of the green light emitting device OLED_G may have a structure of the first electrode 200 of the second light emitting device OLED2 shown in FIG. 8. Accordingly, the first microcavity MC1 and the second microcavity MC2 may be generated. In addition, the light emitting layer 320 may generate green light.

The third sub-pixel SP3 may include the blue light emitting device OLED_B. The blue light emitting device OLED_B may include a first electrode 230, a light emitting layer 330, a second electrode 430, and a capping layer 530. The first electrode 230 of the blue light emitting device OLED_B may include a reflective electrode 231 and a first transparent electrode 232. That is, the first electrode 230 of the blue light emitting device OLED_B may have a structure of the first electrode 200 shown in FIG. 6. In addition, the light emitting layer 330 may generate blue light.

The first electrodes 210, 220, and 230 of the red light emitting device OLED_R, the green light emitting device OLED_G, and the blue light emitting device OLED_B may be disposed in each of the first sub-pixel SP1, the second sub-pixel SP2, and the third sub-pixel SP3.

The reflective electrodes 211, 221, and 231 of the red light emitting device OLED_R, the green light emitting device OLED_G, and the blue light emitting device OLED_B may be formed in common. In addition, the second electrodes 410, 420, and 430 of the red light emitting device OLED_R, the green light emitting device OLED_G, and the blue light emitting device OLED_B may be formed in common. In addition, the capping layers 510, 520, and 530 of the red light emitting device OLED_R, the green light emitting device OLED_G, and the blue light emitting device OLED_B may be formed in common.

The first electrodes 210, 220, and 230 of the red light emitting device OLED_R, the green light emitting device OLED_G, and the blue light emitting device OLED_B may have different structures. That is, a structure of the first electrode may be selectively set for each light emitting device OLED of each sub-pixel SP.

Generally, a light efficiency of a front surface of the display device may be heavily influenced by blue light. Accordingly, the present disclosure discloses that the first electrode 230 of the blue light emitting device OLED_B is formed to include only the reflective electrode 231 and the first transparent electrode 232, thereby generating only the first microcavity MC1. Therefore, since the blue light emitting device OLED_B include a relatively narrow light spectrum, the light efficiency of the front surface may be improved.

In addition, in general, a luminance according to a viewing angle of the display device may be heavily influenced by green light. Accordingly, the present disclosure discloses the first microcavity MC1 and the second microcavity MC2 by forming the first electrode 220 of the green light emitting device OLED_G to include the transflective electrode 223. In addition, by forming the transflective electrode 223 relatively thickly, a width of an optical spectrum of the green light emitting device OLED_G may be further widened. Accordingly, since the green light emitting device OLED_G includes a relatively wide spectrum, the luminance according to the viewing angle may be improved.

In addition, the present disclosure discloses the first microcavity MC1 and the second microcavity MC2 by forming the first electrode 210 of the red light emitting device OLED_R to include the transflective electrode 213. In this case, a width of an optical spectrum of the red light emitting device OLED_R may be adjusted by forming a thickness of the transflective electrode 213 relatively thin. Accordingly, a color according to a viewing angle may be improved by maintaining a color balance between blue light with improved light efficiency of the front surface of the display device and green light with improved the luminance according to the viewing angle.

A display device according to an embodiment of the present disclosure includes a substrate including a plurality of sub-pixels, and a plurality of light emitting devices in the plurality of sub-pixels. And, each of the plurality of light emitting devices includes a first electrode on the substrate, a light emitting layer on the first electrode, and a second electrode on the light emitting layer, wherein the plurality of sub-pixels includes a first sub-pixel provided with a first light emitting device and a second sub-pixel provided with a second light emitting device. And, the first light emitting device generates a first microcavity for a light of a first wavelength band and a second microcavity for a light of a second wavelength band between the first electrode and the second electrode. And, the second light emitting device generates a third microcavity for a light in a third wavelength band between the first electrode and the second electrode.

In the display device according to an embodiment of the present disclosure, a light generated by the light emitting layer of the first light emitting device includes the light of the first wavelength band and the second wavelength band, and a light generated by the light emitting layer of the second light emitting device includes the light of the third wavelength band.

In the display device according to an embodiment of the present disclosure, the first electrode of the first light emitting device includes a first reflective electrode on the substrate, a first transparent electrode on the first reflective electrode, a first transflective electrode on the first transparent electrode, and a second transparent electrode on the first transflective electrode. And, the first microcavity is defined by a distance between the first reflective electrode and the second electrode. And, the second microcavity is defined by a distance between the first transparent electrode and the second electrode.

In the display device according to an embodiment of the present disclosure, a spectrum of a light by the second microcavity is shifted to a shorter wavelength region than a spectrum of a light by the first microcavity.

In the display device according to an embodiment of the present disclosure, the first reflective electrode and the first transflective electrode include metal materials such as aluminum (Al), silver (Ag), copper (Cu), molybdenum (Mo), titanium (Ti), tungsten (W), or chromium (Cr), or alloys thereof

In the display device according to an embodiment of the present disclosure, the first transparent electrode and the second transparent electrode may include a transparent conductive material such as indium tin oxide (ITO) or indium zinc oxide (IZO)

In the display device according to an embodiment of the present disclosure, the first electrode of the second light emitting device includes a second reflective electrode on the substrate and a third transparent electrode on the second reflective electrode. And, the third microcavity is defined by a distance between the second reflective electrode and the second electrode.

In the display device according to an embodiment of the present disclosure, the first electrode of the second light emitting device further includes a second transflective electrode on the third transparent electrode and a fourth transparent electrode on the second transflective electrode. And, a fourth microcavity is further generated by a distance between the second transflective electrode and the second electrode

In the display device according to an embodiment of the present disclosure, a transmittance of the second transflective electrode is greater than a transmittance of the first transflective electrode

In the display device according to an embodiment of the present disclosure, the light emitting layer of the first light emitting device generates green light, and the light emitting layer of the second light emitting device generates red or blue light

In the display device according to an embodiment of the present disclosure, the plurality of sub-pixels further include a third sub-pixel provided with a third light emitting device, wherein the first electrode of the third light emitting device includes a third reflective electrode on the substrate and a fifth transparent electrode on the third reflective electrode. And, a fifth microcavity is defined by a distance between the third reflective electrode and the second electrode

In the display device according to an embodiment of the present disclosure, the light emitting layer of the first light emitting device generates green light, the light emitting layer of the second light emitting device generates red light, and the light emitting layer of the third light emitting device generates blue light.

In the display device according to an embodiment of the present disclosure, a full width at half maximum of a light emitted from the third light emitting device is smaller than a full width at half maximum of a light emitted from the second light emitting device. And, the full width at half maximum of a light emitted from the second light emitting device is less than a full width at half maximum of a light emitted from the first light emitting device.

In the display device according to an embodiment of the present disclosure, the second electrode is a transflective electrode.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a plurality of sub-pixels; and
a plurality of light emitting devices in the plurality of sub-pixels,
wherein each of the plurality of light emitting devices includes a first electrode on the substrate, a light emitting layer on the first electrode, and a second electrode on the light emitting layer,
wherein the plurality of sub-pixels includes a first sub-pixel provided with a first light emitting device and a second sub-pixel provided with a second light emitting device,
wherein the first light emitting device generates a first microcavity for a light of a first wavelength band and a second microcavity for a light of a second wavelength band between the first electrode and the second electrode, and
wherein the second light emitting device generates a third microcavity for a light in a third wavelength band between the first electrode and the second electrode.

2. The display device of claim 1, wherein a light generated by the light emitting layer of the first light emitting device includes the light of the first wavelength band and the second wavelength band, and
wherein a light generated by the light emitting layer of the second light emitting device includes the light of the third wavelength band.

3. The display device of claim 1, wherein the first electrode of the first light emitting device includes a first reflective electrode on the substrate, a first transparent electrode on the first reflective electrode, a first transflective electrode on the first transparent electrode, and a second transparent electrode on the first transflective electrode,
wherein the first microcavity is defined by a distance between the first reflective electrode and the second electrode, and
wherein the second microcavity is defined by a distance between the first transparent electrode and the second electrode.

4. The display device of claim 3, wherein a spectrum of a light by the second microcavity is shifted to a shorter wavelength region than a spectrum of a light by the first microcavity.

5. The display device of claim 3, wherein the first reflective electrode and the first transflective electrode include metal materials such as aluminum (Al), silver (Ag), copper (Cu), molybdenum (Mo), titanium (Ti), tungsten (W), or chromium (Cr), or alloys thereof.

6. The display device of claim 3, wherein the first transparent electrode and the second transparent electrode include a transparent conductive material.

7. The display device of claim 6, wherein the transparent conductive material includes indium tin oxide (ITO) or indium zinc oxide (IZO).

8. The display device of claim 3, wherein the first electrode of the second light emitting device includes a second reflective electrode on the substrate and a third transparent electrode on the second reflective electrode, and
wherein the third microcavity is defined by a distance between the second reflective electrode and the second electrode.

9. The display device of claim 8, wherein the first electrode of the second light emitting device further includes a second transflective electrode on the third transparent electrode and a fourth transparent electrode on the second transflective electrode, and
wherein a fourth microcavity is further generated by a distance between the second transflective electrode and the second electrode.

10. The display device of claim 9, wherein a transmittance of the second transflective electrode is greater than a transmittance of the first transflective electrode.

11. The display device of claim 9, wherein the light emitting layer of the first light emitting device generates green light, and the light emitting layer of the second light emitting device generates at least one of red light and blue light.

12. The display device of claim 9, wherein the plurality of sub-pixels further include a third sub-pixel provided with a third light emitting device,
wherein the first electrode of the third light emitting device includes a third reflective electrode on the substrate and a fifth transparent electrode on the third reflective electrode, and
wherein a fifth microcavity is defined by a distance between the third reflective electrode and the second electrode.

13. The display device of claim 12, wherein the light emitting layer of the first light emitting device generates green light, the light emitting layer of the second light emitting device generates red light, and the light emitting layer of the third light emitting device generates blue light.

14. The display device of claim 12, wherein a full width at half maximum of a light emitted from the third light emitting device is less than a full width at half maximum of a light emitted from the second light emitting device, and
wherein the full width at half maximum of a light emitted from the second light emitting device is less than a full width at half maximum of a light emitted from the first light emitting device.

15. The display device of claim 1, wherein the second electrode is a transflective electrode.
